(19) United States
(12) Patent Application Publication
(10) Pub. No.: US 2011/0247692 A1
(43) Pub. Date: Oct. 13, 2011

(54) Thin Film Type Solar Cell and Method for Manufacturing the Same

(76) Inventor: Tae Hoon Kim, Gyeonggi-do (KR)

(21) Appl. No.: 13/132,070

(22) PCT Filed: Dec. 22, 2009
(86) PCT No.: PCT/KR09/07657

§ 371 Date: May 31, 2011

(30) Foreign Application Priority Data
Dec. 26, 2008 (KR) 10-2008-0134802
Dec. 26, 2008 (KR) 10-2008-0134804
Mar. 4, 2009 (KR) 10-2009-0018479

(51) Int. Cl. H01L 31/0232; H01L 31/18

(52) U.S. Cl. 136/259; 438/69; 257/E31.127

(57) ABSTRACT

A thin film type solar cell and a method for manufacturing the same is disclosed, which is capable of improving cell efficiency through the use of a light-scattering film interposed between a substrate and a front electrode layer so as to increase a path length of solar ray in a semiconductor layer by refracting solar ray at various angles, the thin film type solar cell comprising the substrate; the light-scattering film including a bead and a binder, wherein the binder is provided to bind the bead; the front electrode layer on the light-scattering film; the semiconductor layer on the front electrode layer; and a rear electrode layer on the semiconductor layer.

### BACKGROUND OF THE INVENTION

1. Field of the Invention

The present invention relates to a solar cell, and more particularly, to a thin film type solar cell.

2. Discussion of the Related Art

A solar cell with a property of semiconductor converts a light energy into an electric energy.

A structure and principle of the solar cell according to the related art will be briefly explained as follows. The solar cell is formed in a PN-junction structure where a positive (P)-type semiconductor makes a junction with a negative (N)-type semiconductor. When solar ray is incident on the solar cell with the PN junction structure, holes (+) and electrons (−) are generated in the semiconductor owing to the energy of the solar ray. By an electric field generated in a PN-junction area, the holes (+) are drifted toward the P-type semiconductor and the electrons (−) are drifted toward the N-type semiconductor, whereby an electric power is produced with an occurrence of electric potential.

The solar cell can be largely classified into a wafer type solar cell and a thin film type solar cell.

The wafer type solar cell uses a wafer made of a semiconductor material such as silicon. In the meantime, the thin film type solar cell is manufactured by forming a semiconductor in type of a thin film on a glass substrate.

With respect to efficiency, the wafer type solar cell is better than the thin film type solar cell. However, in the case of the wafer type solar cell, it is difficult to realize a small thickness due to difficulty in performance of the manufacturing process. In addition, the wafer type solar cell uses a high-priced semiconductor substrate, whereby its manufacturing cost is increased.

Even though the thin film type solar cell is inferior in efficiency to the wafer type solar cell, the thin film type solar cell has advantages such as realization of thin profile and use of low-priced material. Accordingly, the thin film type solar cell is suitable for a mass production.

Hereinafter, a related art thin film type solar cell will be described with reference to the accompanying drawings.

FIG. 1 is a cross section view illustrating a related art thin film type solar cell.

As shown in FIG. 1, the related art thin film type solar cell comprises a substrate 10; a front electrode layer 30 on the substrate 10; a semiconductor layer 40 on the front electrode layer 30; a transparent conductive layer 50 on the semiconductor layer 40; and a rear electrode layer 60 on the transparent conductive layer 50.

However, the related art thin film type solar cell has the following disadvantages.

For improving efficiency of the solar cell, the generation rate of hole and electron has to be increased so as to increase a path length of solar ray passing through the semiconductor layer 40. However, it is impossible for the related art thin film type solar cell to obtain the increased path length of solar ray in the semiconductor layer 40, whereby it is difficult to obtain desired cell efficiency.

Generally, the substrate 10 is formed of glass containing alkali ions. During a high-temperature deposition process, the alkali ions contained in the glass substrate 10 are drifted to the front electrode layer 30, whereby the drifted alkali ions serve as impurities, thereby lowering cell efficiency.

### SUMMARY OF THE INVENTION

Accordingly, the present invention is directed to a thin film type solar cell and a method for manufacturing the same that substantially obviates one or more problems due to limitations and disadvantages of the related art.

An object of the present invention is to provide a thin film type solar cell and a method for manufacturing the same, which is capable of improving cell efficiency by increasing a path length of solar ray in a semiconductor layer.

Another object of the present invention is to provide a thin film type solar cell and a method for manufacturing the same, which is capable of improving cell efficiency by preventing alkali-ions contained in a substrate from being drifted to a front electrode layer.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a thin film type solar cell comprising a substrate; a light-scattering film including a bead and a binder, wherein the binder is provided to bind the bead; a front electrode layer on the light-scattering film; a semiconductor layer on the front electrode layer; and a rear electrode layer on the semiconductor layer.

In another aspect of the present invention, there is provided a thin film type solar cell comprising a substrate including a bead therein; a front electrode layer on the substrate; a semiconductor layer on the front electrode layer; and a rear electrode layer on the semiconductor layer.

In another aspect of the present invention, there is provided a method for manufacturing a thin film type solar cell comprising forming a light-scattering film on a substrate, wherein the light-scattering film includes a bead and a binder, the binder for binding the bead; forming a front electrode layer on the light-scattering film; forming a semiconductor layer on the front electrode layer; and forming a rear electrode layer on the semiconductor layer.

In another aspect of the present invention, there is provided a method for manufacturing a thin film type solar cell comprising preparing a flexible substrate including a bead therein; forming a front electrode layer on the flexible substrate; forming a semiconductor layer on the front electrode layer; and forming a rear electrode layer on the semiconductor layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross section view illustrating a related art thin film type solar cell;

FIG. 2 is a cross section view illustrating a thin film type solar cell according to one embodiment of the present invention;

FIG. 3(A to C) is a series of cross sections illustrating various types of bead according to the embodiments of the present invention;

FIG. 4 is a cross section view illustrating a thin film type solar cell according to another embodiment of the present invention;

FIG. 5 is a cross section view illustrating a thin film type solar cell according to another embodiment of the present invention;

FIG. 6(A to E) is a series of cross section views illustrating a method for manufacturing a thin film type solar cell according to one embodiment of the present invention;

FIG. 7(A to E) is a series of cross section views illustrating a method for manufacturing a thin film type solar cell according to another embodiment of the present invention; and

FIG. 8(A to E) is a series of cross section views illustrating a method for manufacturing a thin film type solar cell according to another embodiment of the present invention.

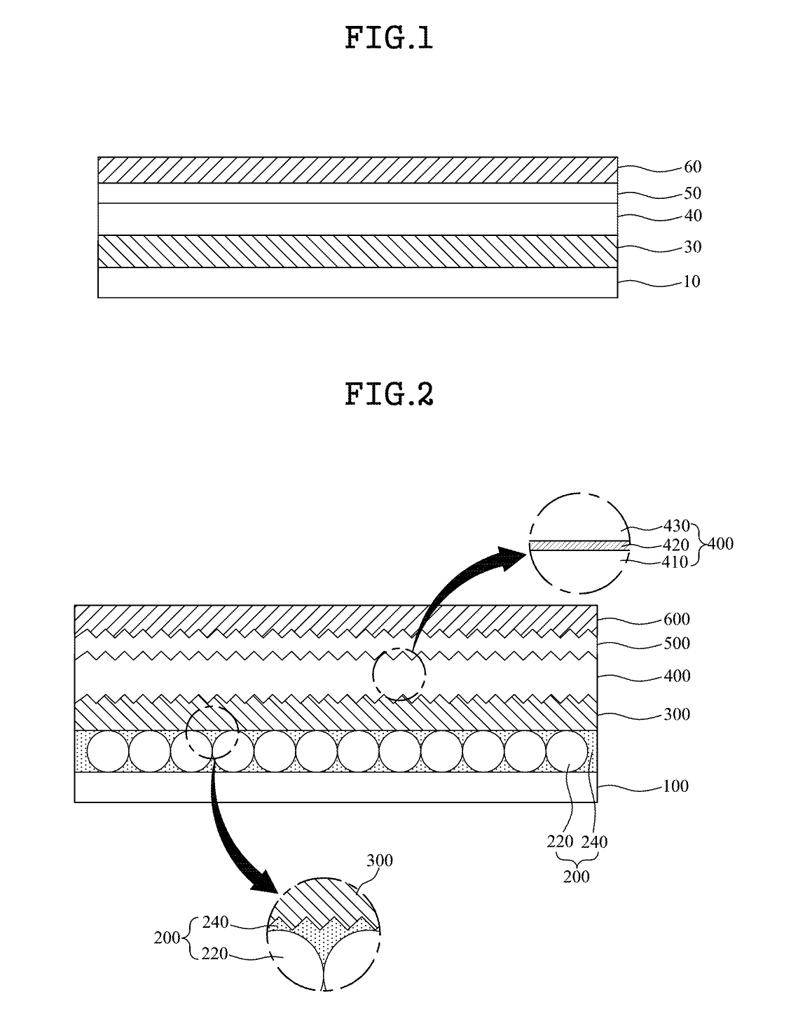

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a thin film type solar cell according to the present invention and a method for manufacturing the same will be described with reference to the accompanying drawings.

### Thin Film Type Solar Cell

FIG. 2 is a cross section view illustrating a thin film type solar cell according to one embodiment of the present invention.

As shown in FIG. 2, the thin film type solar cell according to one embodiment of the present invention includes a substrate 100; a light-scattering film 200; a front electrode layer 300; a semiconductor layer 400; a transparent conductive layer 500; and a rear electrode layer 600.

The substrate 100 is generally made of glass. However, the substrate 100 may be made of transparent plastic. If needed, the substrate 100 may be made of a flexible substrate using polyethyleneterephthalate (PET), polyimide (PI), or polyamide (PA). This flexible substrate enables to obtain a flexible thin film type solar cell. This flexible thin film type solar cell using the flexible substrate can be manufactured by a roll-to-roll method, which enables to lower a manufacturing cost.

The light-scattering film 200 is formed on the substrate 100, wherein the light-scattering film 200 includes a bead 220 and a binder 240. The light-scattering film 200 scatters solar ray passing through the substrate 100 at various angles, and also prevents impurities contained in the substrate 100 from being drifted to the front electrode layer 300.

First, the solar ray is scattered at various angles by the light-scattering film 200, which will be explained as follows.

The light-scattering film 200 includes the bead 220 and the binder 240. Chiefly, the binder 240 is in contact with the substrate 100 and front electrode layer 300. In this case, if a material for the binder 240 is different in refractive index from those of the substrate 100 and front electrode layer 300, the solar ray passed through the substrate 100 is refracted while passing through the binder 240, and is then refracted again while passing through the front electrode layer 300. As a result, the solar ray being incident on the substrate 100 is refracted at various angles, and is incident on the semiconductor layer 400, thereby increasing a path length of the solar ray in the semiconductor layer 400.

Occasionally, the bead 220 may be in contact with the substrate 100 and front electrode layer 300. In this case, if a material for the bead 220 is different in refractive index from those of the substrate 100 and front electrode layer 300, the solar ray being incident on the substrate 100 is refracted at various angles, and is then incident on the semiconductor layer 400 while being refracted at various angles according to the same aforementioned mechanism, whereby the path length of the solar ray is increased in the semiconductor layer 400.

A refractive index of glass used for the general substrate 100 is about 1.52; a refractive index of polyethyleneterephthalate (PET) used for the flexible substrate 100 is about 1.57; and a refractive index of the front electrode layer 300 is about 1.9 to 2.0. The material for the bead 200 or binder 240 has to be selected in consideration to the aforementioned refractive indexes of the substrate 100 and front electrode layer 300. For example, the bead 200 may be made of SiO₂, TiO₂, or CeO₂; and the binder 240 may be made of silicate, but not necessarily.

If the bead 220 and binder 240 contained in the light-scattering film 200 are made of the different materials having the different refractive indexes, the solar ray can be refracted at various angles even in the light-scattering film 200. That is, if the material for the bead 220 is different in refractive index from the material for the binder 240, the solar ray passed through the bead 220 is refracted while passing through the binder 240, and the solar ray passed through the binder 240 is refracted while passing through the bead 220, whereby the solar ray is refracted at various angles.

Instead of forming the bead 220 with the same material, the plurality of beads 220 may be made of the different materials having the different refractive indexes. In this case, the solar ray is refracted at various angles while passing through the plurality of beads 220 made of the different materials having the different refractive indexes.

Also, the bead 220 includes a core and skin. When the solar ray passes through each bead 220 including the core and skin, the solar ray is refracted at various angles.

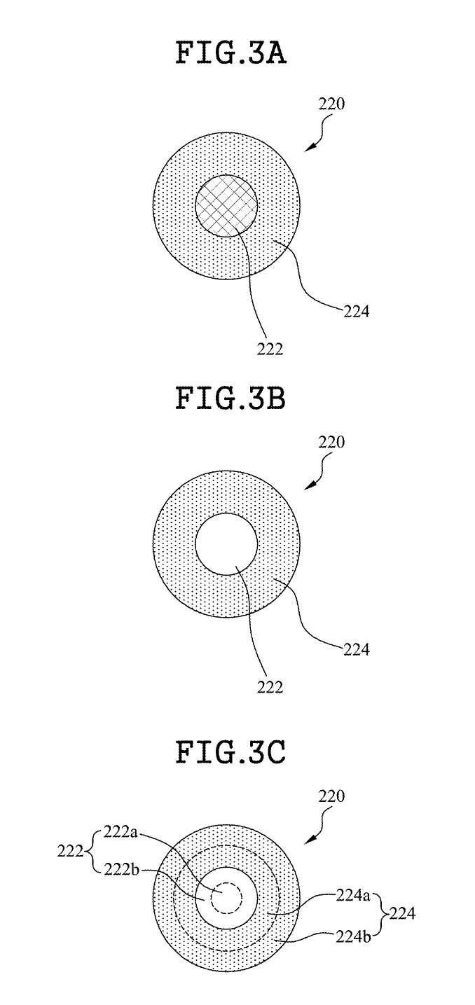

FIG. 3(A to C) is a series of cross sections illustrating various types of bead 220 according to the embodiments of the present invention.

As shown in FIG. 3(A), the bead 220 includes the core 222 and skin 224, wherein the core 222 is surrounded by the skin 224. Also, the material for the core 222 is different in refractive index from the material for the skin 224. Thus, the solar ray is refracted when passing through the core 222 after the skin 224, and is then refracted again when passing through the skin 224 after the core 222.

As shown in FIG. 3(B), the core 222 is formed of air. That is, the hollow-shaped bead 220 is formed by only the skin 224. This structure also enables the same functional effect.

As shown in FIG. 3(C), the core 222 may comprise a plurality of material layers 222a and 222b having the different refractive indexes; and the skin 224 may comprise a plurality of material layers 224a and 224b having the different refractive indexes.

The bead 220 may vary in shape of cross section, for example, circle or oval, whereby the refractive angle of solar ray can be changed diversely.

As known from an expanded view of FIG. 2, the light-scattering film 200 may have an uneven surface so as to diversely change the refractive angle of solar ray.

Next, the light-scattering film 200 can prevent the impurities contained in the substrate 100 from being drifted to the front electrode layer 300, which will be explained as follows. The light-scattering film 200 is positioned between the substrate 100 and the front electrode layer 300. Thus, the light-scattering film 200, and more particularly, the binder 240 contained in the light-scattering film 200 functions as a barrier for a deposition process of the front electrode layer 300, so that it is possible to prevent the impurities contained in the substrate 100 from being drifted to the front electrode layer 300.

The front electrode layer 300 is formed on the light-scattering film 200. Since the front electrode layer 300 is formed on the solar-ray incidence surface, the front electrode layer 300 may be made of a transparent conductive material such as ZnO, ZnO:B, ZnO:Al, SnO₂, SnO₂:F, or ITO (Indium Tin Oxide).

The front electrode layer 300 has an uneven surface which enables to scatter the incident solar ray at various angles, to thereby improve solar-ray absorption efficiency in the semiconductor layer 400.

However, if the uneven surface of the front electrode layer 300 is too excessive, it may cause damages to the semiconductor layer 400 and transparent conductive layer 500 on the front electrode layer 300, whereby the cell efficiency may be lowered. According as the light-scattering film 200 in the thin film type solar cell according to the present invention enables the sufficient light-scattering efficiency, it is unnecessary to provide the excessive uneven surface of the front electrode layer 300. Preferably, the uneven surface of the front electrode layer 300 is adjusted in such a manner that the uneven surface of the front electrode layer 300 is sufficiently small to make no damages to the semiconductor layer 400 and transparent conductive layer 500.

The semiconductor layer 400 is formed on the front electrode layer 300. If the front electrode layer 300 has the uneven surface, the semiconductor layer 400 may also have an uneven surface.

The semiconductor layer 400 is formed in a PIN structure where a P (positive)-type semiconductor layer, an I (intrinsic)-type semiconductor layer, and an N (negative)-type semiconductor layer are deposited in sequence. In the semiconductor layer 400 with the PIN structure, depletion is generated in the I-type semiconductor layer by the P-type semiconductor layer and the N-type semiconductor layer, whereby an electric field occurs therein. Thus, electrons and holes generated by the solar ray are drifted by the electric field, whereby the holes are collected in the front electrode layer 300 through the P-type semiconductor layer, and the electrons are collected in the rear electrode layer 600 through the N-type semiconductor layer. Meanwhile, if forming the semiconductor layer 400 with the PIN structure, the P-type semiconductor layer is firstly formed on the front electrode 300, and then the I-type and N-type semiconductor layers are formed thereon, preferably. This is because a drift mobility of the hole is less than a drift mobility of the electron. In order to maximize the efficiency in collection of the incident light, the P-type semiconductor layer is provided adjacent to the light-incidence face.

The semiconductor layer 400 may be made of silicon-based compounds, or may be made of CIGS (CuInGaSe2) compounds.

As known from an expanded view of FIG. 2, the semiconductor layer 400 may be formed in a tandem structure in which a first semiconductor layer 410, a buffer layer 420, and a second semiconductor layer 430 are deposited in sequence.

Both the first and second semiconductor layers 410 and 430 may be formed in the PIN structure where the P-type semiconductor layer, the I-type semiconductor layer, and the N-type semiconductor layer are deposited in sequence.

The first semiconductor layer 410 may be formed in the PIN structure of amorphous semiconductor material; and the second semiconductor layer 430 may be formed in the PIN structure of microcrystalline semiconductor material.

The amorphous semiconductor material is characterized by absorption of short-wavelength light; and the microcrystalline semiconductor material is characterized by absorption of long-wavelength light. A mixture of the amorphous semiconductor material and the microcrystalline semiconductor material can enhance light-absorbing efficiency, but it is not limited to this type of mixture. That is, the first semiconductor layer 410 may be made of amorphous semiconductor/germanium material, or microcrystalline semiconductor material; and the second semiconductor layer 430 may be made of amorphous semiconductor material, or amorphous semiconductor/germanium material.

The buffer layer 420 is interposed between the first and second semiconductor layers 410 and 430, wherein the buffer layer 420 enables smooth drift of electron and hole by a tunnel junction. The buffer layer 420 may be made of a transparent material, for example, ZnO.

The semiconductor layer 400 may be formed as a triple structure instead of the tandem structure. In case of the triple structure, each buffer layer is interposed between each of first, second and third semiconductor layers included in the semiconductor layer 400.

The transparent conductive layer 500 is formed on the semiconductor layer 400. The transparent conductive layer 500 may be made of a transparent conductive material, for example, ZnO, ZnO:B, ZnO:Al, SnO₂, SnO₂:F, or ITO (Indium Tin Oxide). The transparent conductive layer 500 may have an uneven surface. The transparent conductive layer 500 may be omissible.

The rear electrode layer 600 is formed on the transparent conductive layer 500. The rear electrode layer 600 may be made of a metal material, for example, Ag, Al, Ag+Mo, Ag+Ni, or Ag+Cu.

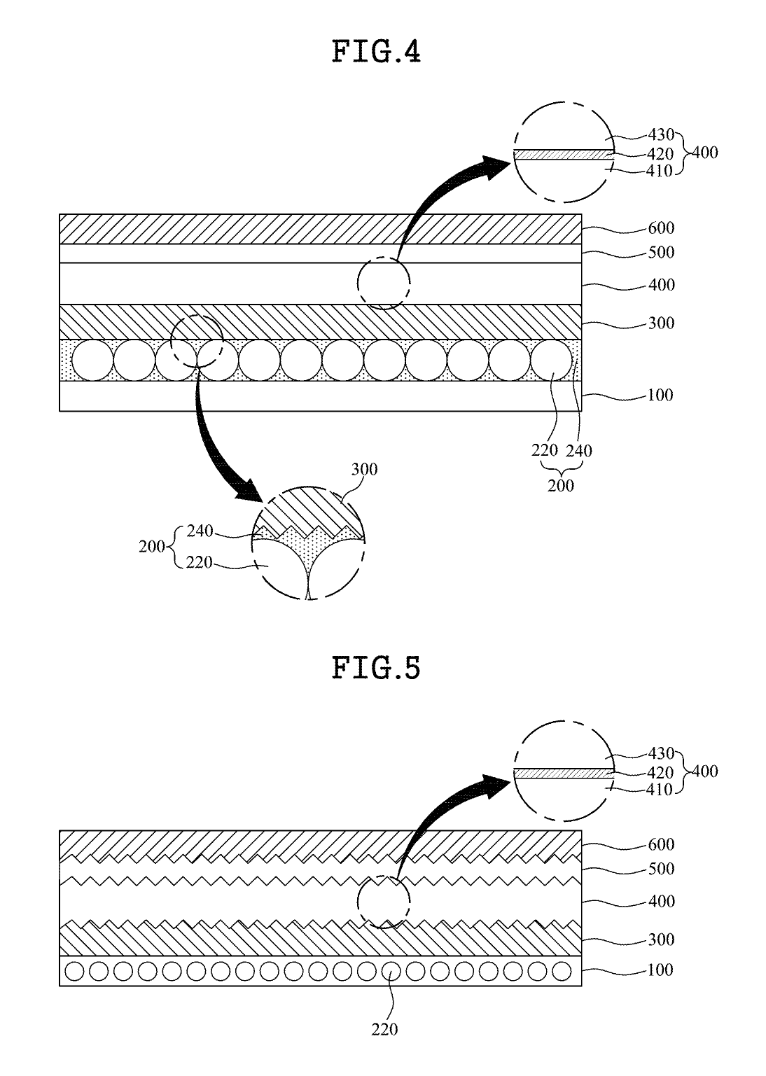

FIG. 4 is a cross section view illustrating a thin film type solar cell according to another embodiment of the present invention.

As shown in FIG. 4, the thin film type solar cell according to another embodiment of the present invention includes a substrate 100; a light-scattering film 200; a front electrode layer 300; a semiconductor layer 400; a transparent conductive layer 500; and a rear electrode layer 600. Except that the front electrode layer 300 is not provided with an uneven surface, the thin film type solar cell according to another embodiment of the present invention is identical in structure to the thin film type solar cell explained with reference to FIG. 2. Thus, a detailed explanation for the same parts will be omitted.

A method for forming the uneven surface of the front electrode layer 300 is to adjust the deposition conditions of the front electrode layer 300 when depositing the front electrode layer 300. That is, the surface of front electrode layer 300 becomes uneven as soon as the front electrode layer 300 is deposited. In this case, it is not easy to adjust the deposition conditions, that is, it is not easy to obtain the desired uneven pattern. The undesired uneven pattern may cause damages to the semiconductor layer 400 and transparent conductive layer 500 on the front electrode layer 300.

Another method for forming the uneven surface of the front electrode layer 300 is to deposit the front electrode layer 300 with a flat surface, and then to apply a chemical etching process to the flat surface of the front electrode layer 300 so as to form the uneven surface of the front electrode layer 300. This method may be complicated due to the additionally-applied chemical etching process, may cause an environmental contamination by chemicals used for the chemical etching process, and also may cause the increase of cost for disposing the chemicals.

Another embodiment of the present invention shown in FIG. 4 discloses that the front electrode layer 300 is not provided with the uneven surface. In case of the present invention, the solar ray is refracted at various angles while passing through the light-scattering film 200. Thus, even though the front electrode layer 300 is not provided with the uneven surface, it makes no difference.

According as the front electrode layer 300 is not provided with the uneven surface, both the semiconductor layer 400 and transparent conductive layer 500 formed on the front electrode layer 300 are not provided with the uneven surfaces. However, the transparent conductive layer 500 may be provided with the uneven surface.

FIG. 5 is a cross section view illustrating a thin film type solar cell according to another embodiment of the present invention.

In case of the thin film type solar cell of FIG. 5, instead of forming a light-scattering film 200 between a substrate 100 and a front electrode layer 300, a bead 220 is included in the substrate 100. Except that, the thin film type solar cell of FIG. 5 is identical in structure to the aforementioned thin film type solar cell of FIG. 2. Thus, the same reference numbers will be used throughout the drawings to refer to the same or like parts, and a detailed explanation for the same parts will be omitted.

The thin film type solar cell of FIG. 5 may be used as a flexible thin film type solar cell using a flexible substrate 100 with the bead 220 included therein, wherein the bead 220 included in the flexible substrate 100 enables to scatter solar ray at various angles. That is, if a material for the bead 220 is different in refractive index from materials for the flexible substrate 100 and front electrode layer 300, the solar ray is diversely refracted while passing through the flexible substrate 100, the bead 220, and the front electrode layer 300, whereby a path length of the solar ray is increased in a semiconductor layer 400.

Also, as mentioned above, if the bead 220 is formed by combining a plurality of beads which are made of the different materials having the different refractive indexes, the solar ray is refracted at various angles while passing through the plurality of beads. Also, each bead 220 includes a core and skin, as shown in FIG. 3(A to C), whereby the solar ray is refracted at various angles while passing through each bead 220.

### Method for Manufacturing Thin Film Type Solar Cell

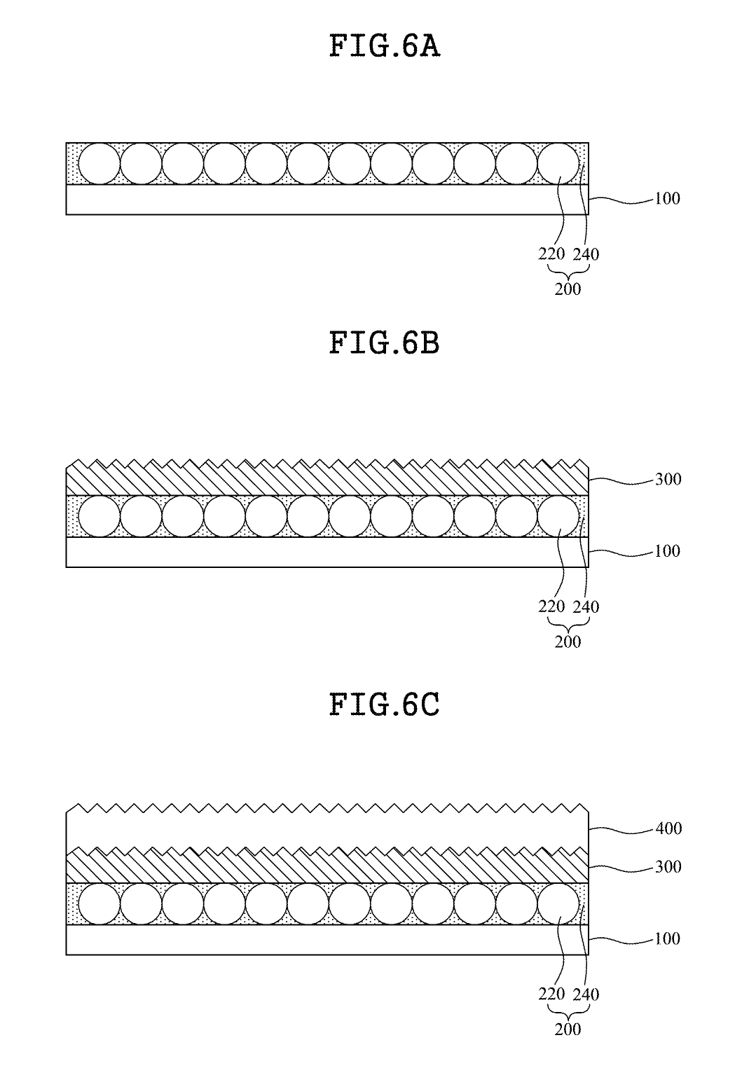

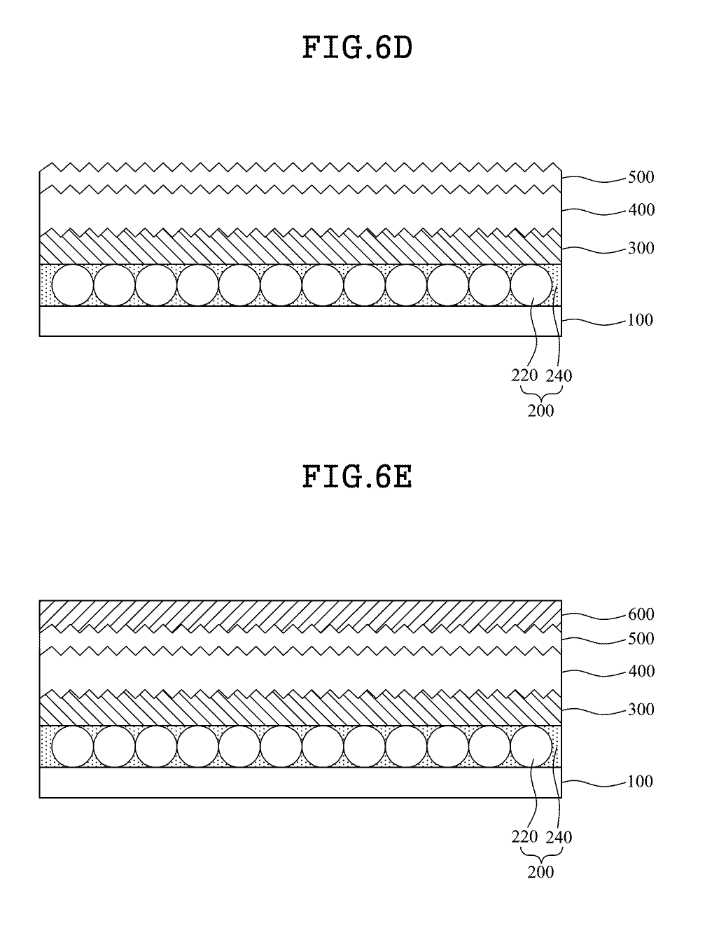

FIG. 6(A to E) is a series of cross section views illustrating a method for manufacturing a thin film type solar cell according to one embodiment of the present invention, which illustrates the method for manufacturing the thin film type solar cell of FIG. 2.

First, as shown in FIG. 6(A), the light-scattering film 200 is formed on the substrate 100, wherein the light-scattering film 200 includes the bead 220, and the binder 240 for binding the bead 220.

The substrate 100 is made of the glass, transparent plastic or flexible substrate.

The light-scattering film 200 may be formed through steps of preparing a paste by uniformly distributing the beads 220 in the binder 240; and carrying out a printing method, a sol-gel method, a dip-coating method, or a spin-coating method using the prepared paste.

After forming the light-scattering film 200 by the aforementioned method, an infrared-ray sintering process or low-temperature/high-temperature sintering process may be additionally applied thereto, thereby resulting in improved cohesion between the substrate 100 and the light-scattering film 200.

The light-scattering film 200 may have the uneven surface. For forming the uneven surface of the light-scattering film 200, a physical contact is applied to the surface of the film formed by the aforementioned printing, sol-gel, dip-coating, or spin-coating method.

The bead 220 and binder 240 contained in the light-scattering film 200 are identical to the aforementioned those, whereby a detailed explanation for the bead 220 and binder 240 will be omitted.

As shown in FIG. 6(B), the front electrode layer 300 is formed on the light-scattering film 200.

The front electrode layer 300 may be formed through steps of depositing the transparent conductive material such as ZnO, ZnO:B, ZnO:Al, SnO₂, SnO₂:F, or ITO (Indium Tin Oxide); and forming the uneven surface in the deposited material layer.

When forming the front electrode layer 300 with the uneven surface, the uneven surface may be directly formed by adjusting the deposition conditions in a deposition process of MOCVD (Metal Organic Chemical Vapor Deposition); or may be formed by applying the etching process to the flat surface of the front electrode layer 300 obtained by sputtering. Herein, the etching process may use photolithography, anisotropic etching using a chemical solution, or mechanical scribing.

As explained above, preferably, the uneven surface of the front electrode layer 300 is adjusted in such a manner that the uneven surface of the front electrode layer 300 is sufficiently small to make no damages to the semiconductor layer 400 and transparent conductive layer 500 to be formed by the following process.

As shown in FIG. 6(C), the semiconductor layer 400 is formed on the front electrode layer 300.

The semiconductor layer 400 may be formed of the silicon-based amorphous semiconductor material through plasma CVD method, wherein the semiconductor layer 400 may be formed in the PIN structure where the P-type semiconductor layer, the I-type semiconductor layer, and the N-type semiconductor layer are deposited in sequence.

The semiconductor layer 400 may be formed in the tandem structure where the first semiconductor layer 410, the buffer layer 420 and the second semiconductor layer 430 are deposited in sequence (See FIG. 2).

As shown in FIG. 6(D), the transparent conductive layer 500 is formed on the semiconductor layer 400.

The transparent conductive layer 500 may be formed by depositing the transparent conductive material such as ZnO, ZnO:B, ZnO:Al, SnO₂, SnO₂:F, or ITO by sputtering or MOCVD (Metal Organic Chemical Vapor Deposition). The transparent conductive layer 500 may be omissible.

As shown in FIG. 6(E), the rear electrode layer 600 is formed on the transparent conductive layer 500.

The rear electrode layer 600 may be formed by depositing the metal material, such as Ag, Al, Ag+Mo, Ag+Ni, or Ag+Cu by sputtering or printing.

If the aforementioned process of FIG. 6(A to E) is applied to the method for manufacturing the flexible thin film type solar cell using the flexible substrate, the process of FIG. 6(A to E) can be carried out through roll-to-roll method.

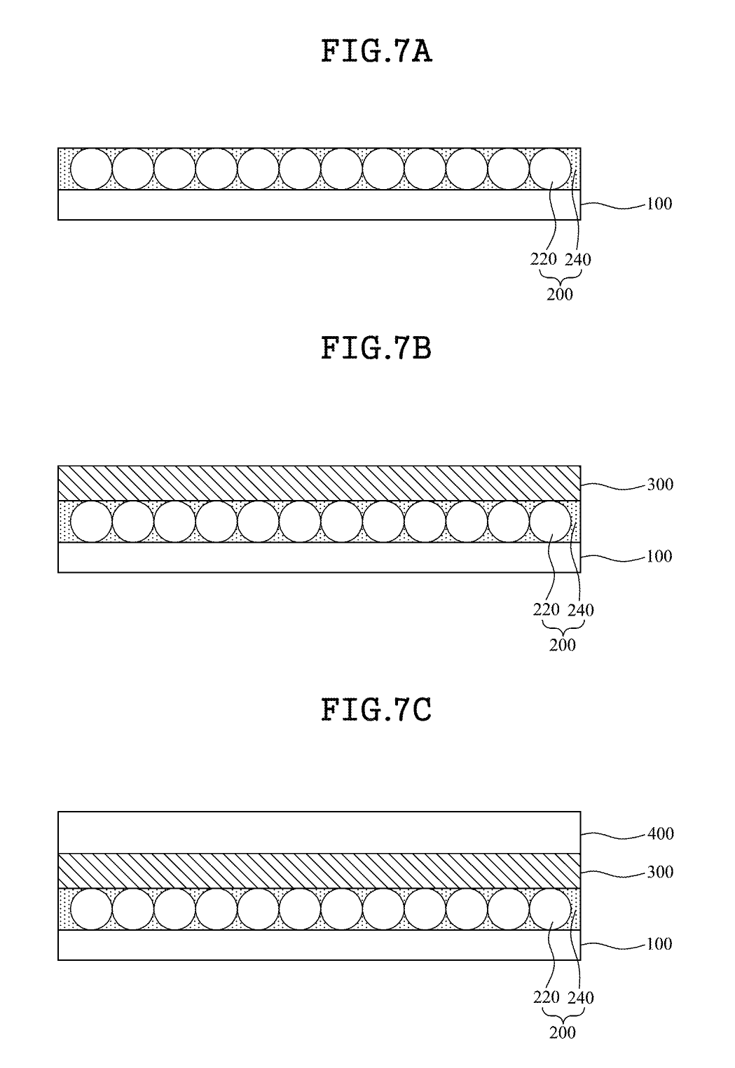

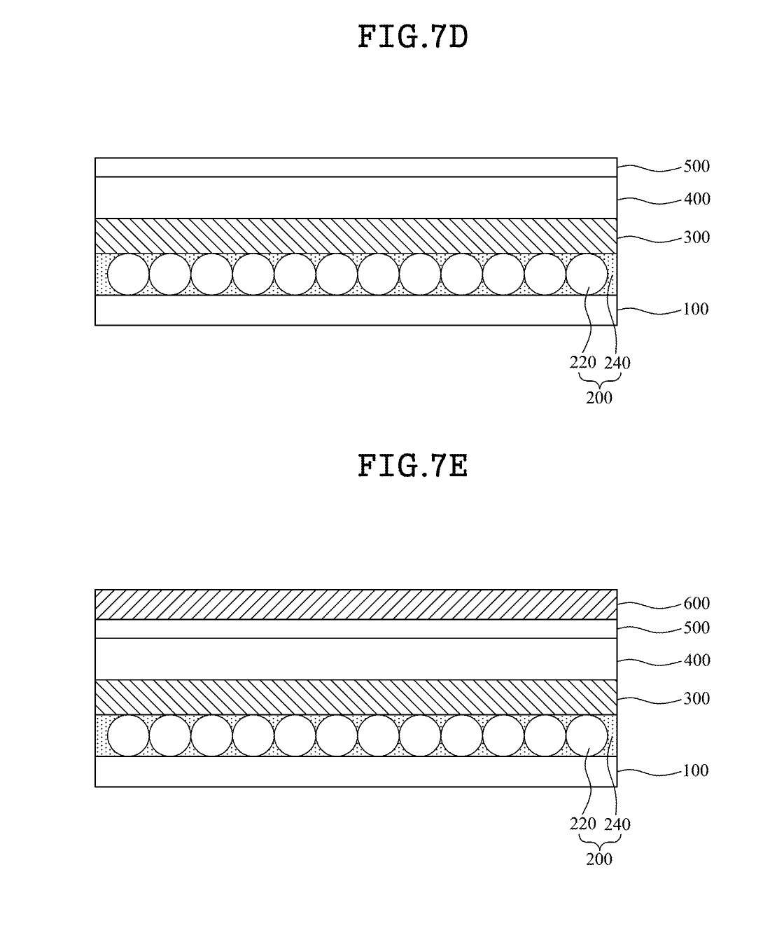

FIG. 7(A to E) is a series of cross section views illustrating a method for manufacturing a thin film type solar cell according to another embodiment of the present invention, which illustrates the method for manufacturing the thin film type solar cell of FIG. 4. A detailed explanation for the same structure as that of the aforementioned embodiment will be omitted.

First, as shown in FIG. 7(A), the light-scattering film 200 is formed on the substrate 100, wherein the light-scattering film 200 includes the bead 220, and the binder 240 for binding the bead 220.

As shown in FIG. 7(B), the front electrode layer 300 is formed on the substrate 100. There is no need to form the uneven surface in the front electrode layer 300. In this respect, the front electrode layer 300 may be deposited by the general sputtering method.

As shown in FIG. 7(C), the semiconductor layer 400 is formed on the front electrode layer 300.

As shown in FIG. 7(D), the transparent conductive layer 500 is formed on the semiconductor layer 400. A process for forming the transparent conductive layer 500 may be omissible.

As shown in FIG. 7(E), the rear electrode layer 600 is formed on the transparent conductive layer 500.

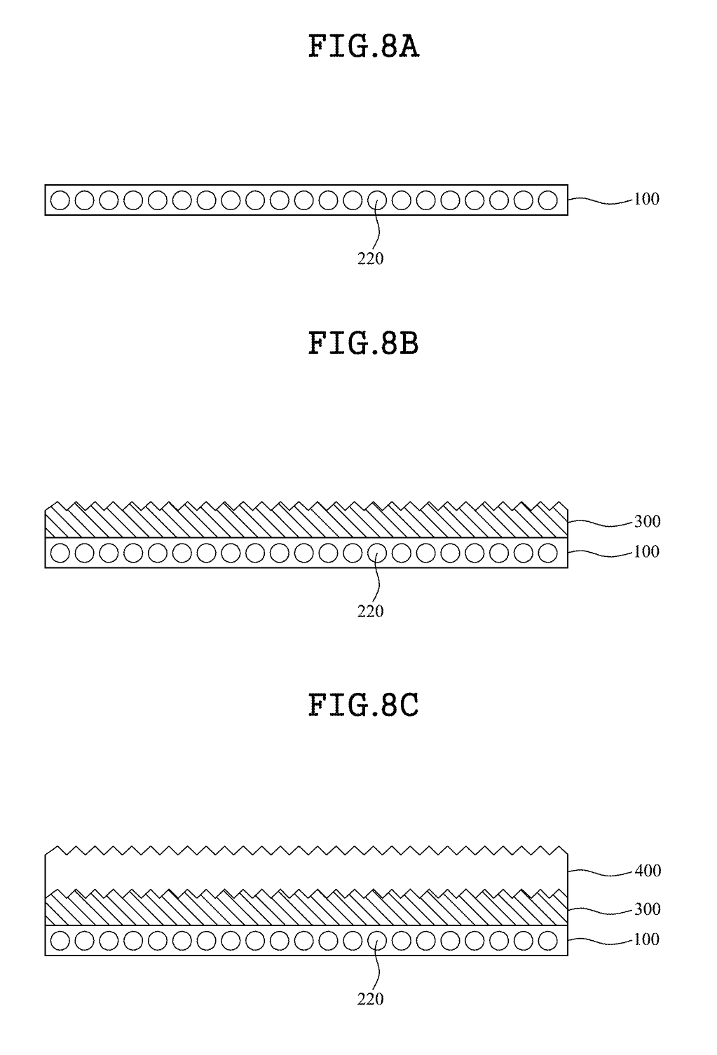

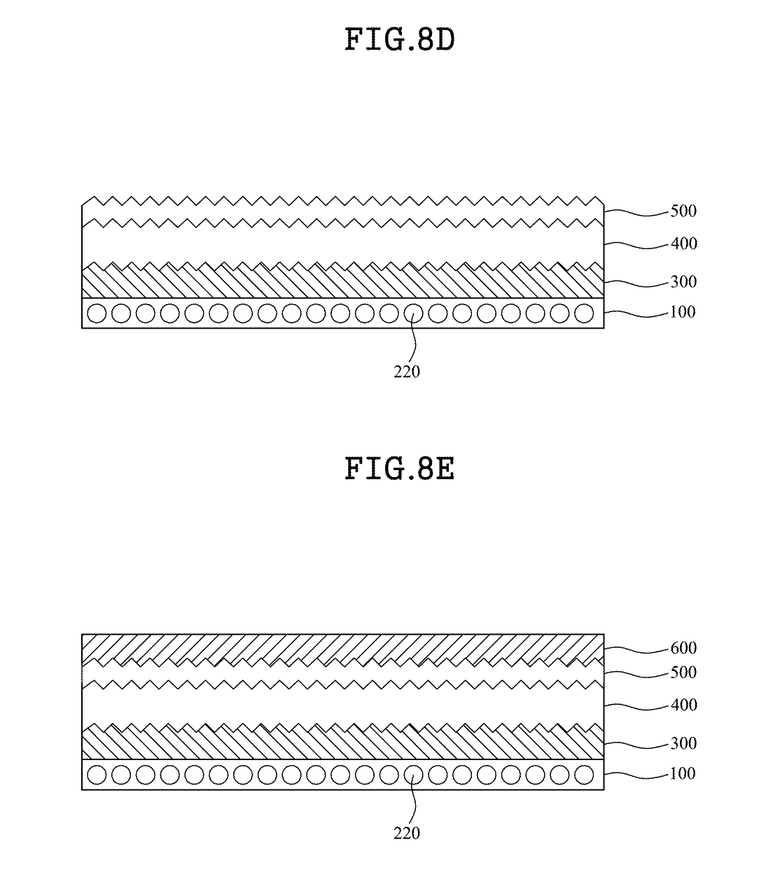

FIG. 8(A to E) is a series of cross section views illustrating a thin film type solar cell according to another embodiment of the present invention, which illustrates the method for manufacturing the thin film type solar cell of FIG. 5. A detailed explanation for the same structure as that of the aforementioned embodiment will be omitted.

First, as shown in FIG. 8(A), the substrate 100 with the bead 220 contained therein is prepared.

The substrate 100 with the bead 220 contained therein may be prepared through steps of forming a thin film by including the bead 220 in molten liquid for substrate; and curing the formed thin film.

A detailed structure for the bead 200 is explained above, which is the same as the aforementioned structure.

As shown in FIG. 8(B), the front electrode layer 300 is formed on the substrate 100.

As shown in FIG. 8(C), the semiconductor layer 400 is formed on the front electrode layer 300.

As shown in FIG. 8(D), the transparent conductive layer 500 is formed on the semiconductor layer 400. A process for forming the transparent conductive layer 500 may be omissible.

As shown in FIG. 8(E), the rear electrode layer 600 is formed on the transparent conductive layer 500.

The thin film type solar cell according to the present invention and the method for manufacturing the same are not limited to the aforementioned embodiments. Especially, if the present invention is applied to a large-sized substrate, the large-sized substrate may be divided into a plurality of unit cells, and the plurality of unit cells are connected in series.

Accordingly, the thin film type solar cell according to the present invention and the method for manufacturing the same has the following advantages.

The thin film type solar cell according to the present invention is provided with the light-scattering film 200 between the substrate 100 and the front electrode layer 300, whereby the solar ray can be diversely refracted at various angles, thereby resulting in the increased path length of solar ray. As a result, the cell efficiency can be improved.

The pattern for refracting the solar ray can be easily adjusted by appropriately changing the material and pattern of the bead 220 and binder 240 contained in the light-scattering film 200, thereby resulting in optimization for improvement of the cell efficiency.

Also, the light-scattering film 200 is formed between the substrate 100 and the front electrode layer 300, the light-scattering film 200 functions as the barrier for the deposition process of the front electrode layer 300, so that it is possible to prevent the impurities contained in the substrate 100 from being drifted to the front electrode layer 300, thereby preventing the cell efficiency from being lowered.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A thin film type solar cell comprising:
a substrate;
a light-scattering film including a bead and a binder, wherein the binder is provided to bind the bead;
a front electrode layer on the light-scattering film;
a semiconductor layer on the front electrode layer; and
a rear electrode layer on the semiconductor layer,
wherein a surface of the light-scattering film facing the front electrode layer is not uneven.

2. The thin film type solar cell of claim 1, wherein a material for the light-scattering film has a different in refractive index from a material for the substrate or front electrode layer.

3. The thin film type solar cell of claim 1, wherein a material for the bead in the light-scattering film has a different refractive index from a material for the binder in the light-scattering film.

4. The thin film type solar cell of claim 1, wherein the bead comprises a plurality of beads whose refractive indexes are different from one another.

5. The thin film type solar cell of claim 1, wherein the bead includes a core and a skin; wherein the core is surrounded by the skin, and a material for the core has a different refractive index from a material for the skin.

6. The thin film type solar cell of claim 1, wherein the surface of the light-scattering film facing the front electrode layer is substantially even.

7. The thin film type solar cell of claim 1, wherein a surface of the front electrode layer facing the semiconductor layer does not have an uneven surface.

8. The thin film type solar cell of claim 1, wherein the semiconductor layer comprises a first semiconductor layer and a second semiconductor layer with a buffer layer therebetween, wherein the first semiconductor layer comprises a P type semiconductor layer and the second semiconductor layer comprises an N type semiconductor layer.

9. The thin film type solar cell of claim 1, further comprising a transparent conductive layer between the semiconductor layer and the rear electrode layer.

10. A thin film type solar cell comprising:
a substrate including a bead therein;
a front electrode layer on the substrate;
a semiconductor layer on the front electrode layer; and
a rear electrode layer on the semiconductor layer,
wherein a material for the bead has a different refractive index from materials for the substrate and front electrode layer, and
at least one of a surface of the front electrode layer facing the substrate and a surface of the front electrode layer facing the semiconductor layer does not have an uneven surface.

11. (canceled)

12. A method for manufacturing a thin film type solar cell comprising:
forming a light-scattering film on a substrate, wherein the light-scattering film includes a bead and a binder, the binder for binding the bead;
forming a front electrode layer on the light-scattering film;
forming a semiconductor layer on the front electrode layer; and
forming a rear electrode layer on the semiconductor layer,
wherein a surface of the light-scattering film facing the front electrode layer does not have an uneven surface.

13. (canceled)

14. The method of claim 12, wherein forming the light-scattering film comprises a sintering process after formation of the film so as to improve a cohesion between the substrate and the light-scattering film.

15. (canceled)

16. (canceled)

17. (canceled)

18. The method of claim 12, wherein the bead includes a core and a skin; wherein the core is surrounded by the skin, and a material for the core has a different refractive index from a material for the skin.

19. (canceled)

20. (canceled)

21. (canceled)

22. (canceled)

23. (canceled)

24. A method for manufacturing a thin film type solar cell comprising:
preparing a flexible substrate including a bead therein;
forming a front electrode layer on the flexible substrate;
forming a semiconductor layer on the front electrode layer; and
forming a rear electrode layer on the semiconductor layer,
wherein a material for the bead has a different refractive index from materials for the substrate and front electrode layer, and
at least one of a surface of the front electrode layer facing the substrate and a surface of the front electrode layer facing the semiconductor layer does not have an uneven surface.

25. (canceled)

26. The method of claim 24, wherein the bead includes a core and a skin, the core is surrounded by the skin, and a material for the core has a different refractive index from a material for the skin.

27. The thin film type solar cell of claim 1, wherein a surface of the front electrode layer facing the semiconductor layer has an uneven surface.

28. The thin film type solar cell of claim 11, wherein the bead includes a core and a skin, the core is surrounded by the skin, and a material for the core has a different refractive index from a material for the skin.

29. The thin film type solar cell of claim 11, wherein a surface of the front electrode layer facing the semiconductor layer has an uneven surface.

30. The thin film type solar cell of claim 11, wherein the bead comprises a plurality of beads whose refractive indexes are different from one another.

31. The thin film type solar cell of claim 11, wherein the bead comprises a plurality of beads whose cross sections are different from one another.
